(19) United States
(12) Patent Application Publication
(10) Pub. No.: US 2008/0070803 A1
(43) Pub. Date: Mar. 20, 2008

(54) Electrochemical Treatment Of Substrates

(76) Inventor: Ryan D. Egeland, Oxford (GB)

Correspondence Address: WENDEROTH, LIND & PONACK, L.L.P., 2033 K STREET N. W., SUITE 800, WASHINGTON, DC, 20006-1021, US

(21) Appl. No.: 10/574,818

(22) PCT Filed: Oct. 15, 2004
(86) PCT No.: PCT/GB04/04390

§ 371 Date: Jun. 20, 2007

(30) Foreign Application Priority Data
Oct. 15, 2003 (GB) 0324154.4
Aug. 9, 2004 (GB) 0417695.4

(51) Int. Cl. C40B 50/00; B01J 19/08; C40B 60/14; C25F 3/02

(52) U.S. Cl. 506/23; 204/242; 205/640; 205/687; 205/704; 506/40

(57) ABSTRACT

A method of electrochemically treating a substrate is provided comprising the steps of: (a) providing an electrolyte in contact with the substrate; (b) providing a device which faces the substrate and is in contact with the electrolyte, the device having: (i) a common first electrode arranged to define cells therein; and (ii) a plurality of individually addressable second electrodes, wherein a plurality of the cells contain individually addressable second electrodes; and (c) altering the potential of at least one of the second electrodes relative to the common first electrode so that: (i) the common first electrode generates a first redox product; and (ii) the at least one of the second electrodes generate a second redox product which is able to modify a region of the substrate facing the at least one electrodes, wherein the electrolyte is such that the second redox product is quenchable by the first redox product.

All documents cited herein are incorporated by reference in their entirety.

### TECHNICAL FIELD

This invention is in the field of electrochemical patterning of substrates. More particularly, this invention relates to a method of electrochemically modifying substrates and to a device that may be used in such methods.

### BACKGROUND ART

There are many occasions where it is required to provide a pattern of a material on a substrate. Examples of such patterned substrates include semiconductor chips and devices on printed circuit boards. More recently, patterns of oligonucleotides bound to a solid surface have been produced to form DNA chips. DNA chips comprise arrays of various DNA sequences bound to a substrate at specific sites.

Various methods of fabricating patterned substrates exist. Photolithography is an example of such a method. In photolithography, specific regions of a substrate surface are covered with a photolithographic mask and the exposed regions are modified by exposure to ultraviolet (UV) light. Photolithography has been used widely in the fabrication of semiconductor devices.

Photolithography has also been employed in the manufacture of DNA chips. In this method, oligonucleotides having photolabile protecting groups are bound to a solid surface. A region of the surface is covered with a photolithographic mask and the exposed regions of the surface irradiated with UV light, thereby removing the photolabile protecting groups from the exposed region of the surface (Ramsay (1998) Nature Biotechnology 16:40-44).

WO93/22480 and U.S. Pat. No. 5,667,667 describe a method of treating a surface using an electrochemical method. In this method, there is an arrangement where an electrolyte overlays a surface and an array of electrodes adjacent to the surface. By altering the potential of one or more electrodes in the array, the surface adjacent to the one or more electrodes may be modified. This method may be used during the synthesis of polymers by removing protecting groups of particular areas of polymer bound to the surface. The surface is then exposed to monomers. Reaction of the unprotected polymer with the monomers enables further growth of the polymer bound to the surface. This method may be used to generate large arrays of diverse polypeptides or other polymers. The electrolyte employed in WO93/22480 is a solution of triethylamine and sulphuric acid in acetonitrile.

U.S. Pat. No. 6,093,302 also describes an electrochemical method of growing arrays of oligonucleotides on a substrate. Species generated at specific electrodes react with a substrate close to the electrode. The use of a buffering or scavenging solution is described. The buffering or scavenging solution is intended to improve the resolution of the substrate being treated by reacting with reagents that move away from the immediate vicinity of the electrodes. However, a bulk solution containing a buffering or scavenging substance has the disadvantage of quenching not only those reagents that diffuse away from specific electrodes, but also reagents which are intended to react at a substrate adjacent to a specific electrode.

Schuster et al. (2000) Science 289:98-101 describes another method of improving the resolution of an electrochemical method of treating a surface. Schuster employs a complicated sequence of current pulses to limit diffusion time.

WO03/20415 describes a further method of improving the resolution of an electrochemical method of treating a surface. This is achieved by selecting an electrolyte such that a first redox product generated by a first electrode is quenchable by the redox product generated by a second electrode. By arranging the first electrode in close proximity to the second electrode, diffusion of the second redox product is controlled.

Using the method disclosed in WO03/20415, the first electrodes are switched on and off simultaneously with the second electrodes. This provides an electrochemical “patterning unit” that consists of a second electrode and at least one first electrode. Switching of all first and second electrodes is suitable when the total number of electrodes (that is, anodes and cathodes) is small, as each electrode can be connected directly to off-chip circuitry designed to control the current switching. However, as the number of electrodes on a device increases, it becomes more difficult and costly to connect each electrode independently.

There is a need for an improved method of modifying a substrate using electrochemical means. In particular, there is a need for a method of modifying a substrate with improved resolution.

### DISCLOSURE OF THE INVENTION

According to the present invention there is provided a method of electrochemically treating a substrate, which method comprises the steps of:
(a) providing an electrolyte in contact with the substrate;
(b) providing a device which faces the substrate and is in contact with the electrolyte, the device having:
   (i) a common first electrode arranged to define cells therein; and
   (ii) a plurality of individually addressable second electrodes, wherein a plurality of the cells contain individually addressable second electrodes; and
(c) altering the potential of at least one of the second electrodes relative to the common first electrode so that:
   (i) the common first electrode generates a first redox product; and
   (ii) the at least one of the second electrodes generate a second redox product which is able to modify a region of the substrate facing the at least one electrodes,
      wherein the electrolyte is such that the second redox product is quenchable by the first redox product.

Electrochemical patterning at high resolution is achieved by the method of the present invention. By having a common first electrode arranged to define cells, the method dispenses with the requirement of individually addressing a number of different first electrodes in proximity to the second electrode in order to control diffusion of the second redox product by the quenching process. The arrangement of the common first electrode in relation to the second electrodes simplifies the electrical connections and the electronics required to pattern a substrate at very high resolution. Moreover, because of the decrease in electrical connections required for the common first electrode compared with prior art devices, a higher density of second electrodes may be provided, thereby enabling patterning of a substrate at very high resolution. This arrangement of electrodes also has the advantage that by having a common first electrode the number of transistors required to operate the device may be significantly reduced thereby lowering device fabrication costs, since the cost of the device is generally dependent on the number of transistors. Further advantages of having a common first electrode are that power consumption can be reduced, which enables more frequent use of low power electronics, and that the device does not require synchronisation between the cathode and anode switching.

The invention also provides a device for electrochemically modifying a substrate having:
(i) a common first electrode arranged to define cells therein; and
(ii) a plurality of individually addressable second electrodes,
   wherein:
a plurality of the cells contain individually addressable second electrodes;
the common first electrode and the plurality of second electrodes are in contact with an electrolyte; and
the electrolyte is such that the common first electrode is able to generate a first redox product, the second electrode is able to generate a second redox product, and the second redox product is quenchable by the first redox product.

### The Device

In the method and the device of the invention, the first electrode is common in the sense that all elements of the first electrode are connected electrically. In this way, the entire first electrode can be held at a single potential. The common first electrode may be singly addressable such that the potential of the first electrode may be altered by addressing a single connection. Alternatively, the common first electrode may be a bus line which is neither switchable nor addressable.

Preferably, the common first electrode is a cathode.

The common first electrode may be arranged in any way suitable to define cells. For example, the common first electrode may have a geometry in which there is a substantially regular pattern or a substantially irregular pattern. The common first electrode may have a mixture of patterns. Examples of regular patterns that the common first electrode may adopt are a grid, a net, a honeycomb, a series of intersecting circles or other tessellating shapes, for example as shown in FIGS. 1 to 5. The grid may be a rectilinear grid. The spaces within the constituent parts of the regular or irregular pattern adopted by the common first electrode define cells. As well as being of the same or differing shape, the cells may be uniform in size or of a range of sizes.

The common first electrode may further comprise a dielectric arranged to define cells. For example, the dielectric may have a geometry in which there is a substantially regular pattern or a substantially irregular pattern. The dielectric may have a mixture of patterns. An example of a regular pattern that the dielectric may adopt is an array of shapes, e.g. squares or circles, especially squares. The constituent parts of the regular or irregular pattern adopted by the dielectric define cells. As well as being of the same or differing shape, the cells may be uniform in size or of a range of sizes. An electrode in this embodiment may, for example, comprise a conducting or semi-conducting layer further comprising a dielectric layer on the conducting or semi-conducting layer in the form of an array of shapes (e.g. squares) arranged to define cells, as for example shown in FIGS. 9 and 10. Optionally, as for example shown in FIGS. 9 and 10, the second electrodes may be mounted upon the dielectric.

It is not essential that the cells are entirely segregated from each other by the common first electrode. Embodiments are envisioned in which there exist gaps in the pattern of arrangement of the common first electrode surrounding second electrodes. However, these gaps are sufficiently small that the second redox product is substantially confined to the cell in which the particular second electrode is located. In general, however, cells will be separated from each other by the common first electrode.

The common first electrode may be in the form of a sheet with punched holes in which second electrodes are positioned. In this embodiment, the punched holes define cells. Alternatively, the common first electrode may substantially comprise lines of wires forming a grid or net-like structure, for example.

Preferably the arrangement of the common first electrode results in at least n×10⁶ cells, where n is 0.5, 0.6, 0.7, 0.8, 0.9, 1.0, 1.1, 1.2, 1.3, 1.4, 1.5, 1.6, 1.7, 1.8, 1.9, 2.0 or more.

Preferably, the arrangement of the common first electrode is such that the distance between the centre of a cell and the centre of at least one of its immediate neighbour cells is less than 0.5 mm. For instance, 0.1-300 μm; 0.1-200 μm; 1-100 μm; 10-60 μm. Typical centre to centre distances are 0.297 mm, 0.294 mm, 0.2805 mm, 0.270 mm, 0.264 mm, 0.260 mm, 0.255 mm, 0.248 mm, 0.099 mm, 0.098 mm, 0.0935 mm, 0.090 mm, 0.088 mm, 0.0867 mm, 0.085 mm, 0.0827 mm, etc.

A plurality of the cells contain second electrodes. Any individual cell may contain one or more second electrodes (e.g. 1, 2, 3, 4 or more). A single second electrode per cell is preferred. Some cells may be empty in that they do not contain a second electrode.

The second electrodes are individually addressable. In this way a specific potential may be applied to any specific second electrode in the device. The ability to address any specific second electrode makes it possible to electrochemically modify in isolation the region of the substrate facing the cell in which the second electrode is located.

Preferably, second electrodes are anodes.

The second electrodes may be addressed using any suitable circuitry, for example by direct connection from an electrode to a bond pad on the perimeter of the device, by CMOS switching circuitry, or by transistor-based circuitry (e.g. TFT circuitry). Preferably, the second electrodes are addressed using TFT circuitry such as used in liquid crystal display panels.

The second electrodes may be of any suitable size so as to lie within cells defined by the common first electrode. Preferably, all the second electrodes in the device are of substantially the same size.

The second electrodes in the device are preferably arranged in an array. The array may be of any regular or irregular shape. The geometry of typical regular arrays of second electrodes will depend on the geometry of the cells but includes squares, rectangles, hexagonal grids and concentric circles. Preferably, the array of second electrodes is at least a 10×10 matrix, preferably a 100×100 matrix, preferably at least a 640×350 matrix, preferably at least a 800×600 matrix, preferably at least a 1024×768 matrix, preferably at least a 1280×768 matrix, preferably at least a 1280×1024 matrix, preferably at least a 1600×1200 matrix, preferably at least a 1920×350 matrix, preferably at least a 2400×600 matrix, preferably at least a 3072×768 matrix, preferably at least a 3840×768 matrix, preferably a 3840×1024 matrix.

Preferably, the distance between the centre of a second electrode and the centre of at least one of its neighbouring second electrodes is less than 0.5 mm. For instance, 0.1-300 μm; 0.1-200 μm; 1-100 μm; 10-60 μm. Typically, centre to centre distanced are 0.297 mm, 0.294 mm, 0.2805 mm, 0.270 mm, 0.264 mm, 0.260 mm, 0.255 mm, 0.248 mm, 0.099 mm, 0.098 mm, 0.0935 mm, 0.090 mm, 0.088 mm, 0.0867 mm, 0.085 mm, 0.0827 mm, etc.

Preferably there are at least n×10⁶ second electrodes, where n is 0.5, 0.6, 0.7, 0.8, 0.9, 1.0, 1.1, 1.2, 1.3, 1.4, 1.5, 1.6, 1.7, 1.8, 1.9, 2.0 or more.

The ratio of the number of cells to the number of second electrodes may be <1 (e.g. some cells are empty), 1 (e.g. all cells contain one second electrode), or >1 (e.g. all cells contain at least one electrode, with some cells containing two electrodes).

The second electrodes may be of any suitable shape. Typically, the second electrodes are circular, square or rectangular. Preferably, all the second electrodes in the device have the same shape.

Preferably, the device comprises a support on which the common first electrode is positioned and a support on which the second electrodes are positioned. Preferably, the common first electrode is mounted on the same support as the second electrodes. The support is typically an insulating surface. The support may be any suitable material or mixture of materials such as an insoluble polymer, ceramic oxides (e.g. alumina) or oxidized silicon wafers. Preferably, the support is an oxidized silicon wafer.

Each of the second electrodes and the common first electrode are arranged on the support such that the second redox product is substantially confined to the cell in which the particular second electrode generating that second redox product is located. Typical arrangements of the first and second electrodes on the support include the first and second electrodes independently being flush with the surface of the support, protruding above or protruding below the surface of the support. Preferably, all the first and second electrodes in the device protrude above the support.

The common first electrode and the second electrodes may be composed of any suitable conducting or semiconducting material. Typically, the common first electrode and second electrodes are independently selected from indium tin oxide (ITO), iridium, platinum, palladium, gold, silver, copper, nickel, zinc, titanium, tungsten, aluminium and alloys of these metals. Preferably, the common first electrode and the second electrodes comprise ITO and/or iridium. An advantage of using iridium is that it is highly conductive and chemically inert Iridium does not suffer from degradation at the high electrical potentials which may be employed using the method of the present invention. Iridium tends not to suffer from degradation during electrolysis and adheres well to materials such as oxidized silicon wafers.

In one preferred arrangement, the common first electrode and second electrodes comprise a coating of iridium on another material, such as ITO. Typically, at least the second electrodes are derived from existing liquid crystal display devices. In this case, the second electrodes may be coated with iridium in order to make the device more highly compatible for use during DNA synthesis applications.

Preferably, the device comprises an array of second electrodes, which are formed from deposits of conducting material spaced apart in an array on the surface of an electrically insulating material, each deposit being provided with electrical connecting means for altering its potential. In a typical procedure, a positive organic photoresist is applied to a silicon dioxide layer on a silicon wafer. The photoresist is exposed to UV light through a suitable photomask, revealing areas of silicon dioxide. Iridium metal is deposited on the surface of the material using an electron-beam gun. Removal of the photoresist layer then reveals the array of second electrodes. Where the conducting material is iridium, the iridium electrodes are subsequently annealed in air to promote adhesion to the wafer surface. Preferably, after deposition, the iridium is annealed in air at a temperature in the range of 200-500° C. Typically, the iridium is annealed at about 350° C. for a period of 15 minutes to 3 hours, preferably about 1 hour. The annealing step improves adhesion of the iridium to silicon dioxide.

Preferably, the common first electrode is formed by depositing a conducting material, preferably iridium, in an appropriate pattern between the second electrodes in the array, as described above. In an alternative embodiment, the common first electrode is formed by removing areas of insulating material between the second electrodes to reveal areas of an underlying sheet of conducting material.

Advantageously, the second electrodes, the support on which the second electrodes are positioned and the circuitry connecting the second electrodes are as found in liquid crystal display devices, particularly those used for colour displays such as televisions, computer monitors and laptop computers. The second electrodes correspond to the switched anode in such a device. Typically, the circuitry in such an array is based on TFT electronics. The use of circuitry based on TFT electronics is advantageous since it allows for exploitation of existing manufacturing techniques and processes.

The device may be incorporated into a flow cell arrangement, e.g. comprising a piston and cylinder reaction chamber. The substrate is attached to an end of the piston and the device is placed at an end face of the cylinder facing the substrate. DNA synthesis reagents and electrolyte solutions may be introduced and removed through ports in the sides of the cylinder. In this way, neither the device nor the substrate need be moved when changing between the electrolyte and the DNA synthesis reagents. Having the substrate mounted on a piston allows adjustment of the position of the substrate relative to the device.

### Electrolyte

The electrolyte is capable of producing two different redox products during electrolysis, and these are able to quench each other (i.e. to react with each other). The first redox product reacts with the second redox product and modifies its reactivity so that the second redox product does not react in the same manner as it would in its original form. The reaction between the first redox product and the second redox product will prevent the second redox product from modifying a substrate. For example, in the case where the second redox product is an acid, the first redox product may be a base. The reaction between the acid and the base quenches the acid and prevents it from modifying a substrate.

Preferably, the electrolyte is a mixture or a solution comprising more than one substance and the first and second redox products are generated from separate substances in the electrolyte.

In a preferred embodiment, the quenching reaction will regenerate one or more of the original substances in the electrolyte. Preferably, the quenching reaction results in substantially total regeneration of the electrolyte. In this way, there is substantially no net change in the composition of the electrolyte following the steps of electrolysis and subsequent quenching. For example, an electrolyte may contain components AB and CD in solvent E. Electrolysis of the electrolyte may result in the production of redox products AB′ and CD′ in solvent E. Quenching of AB′ by CD′ results in the regeneration of AB and CD in solvent E.

Preferably, neither electrolysis of the electrolyte nor the quenching reaction produces gaseous products.

The electrolytes used in the present invention may comprise any suitable solvent, such as water, THF (tetrahydrofuran), methanol, ethanol, DMF (dimethylformamide), dichloromethane, diethyl ether, DMSO (dimethylsulfoxide) or acetonitrile. The skilled person will appreciate that the choice of solvent may influence the kinetics or equilibrium of the redox reactions at the electrodes and/or the quenching reaction. The solvent may affect the reactivity of a species in solution by, for example, complex formation, hydrogen bonding, dipole-dipole interactions or charge delocalisation. Preferably, the solvent is an aprotic solvent which is able to stabilise a radical anion. Examples of aprotic solvents are dichloromethane, DMF, DMSO, acetonitrile and THF. More preferably, the solvent is acetonitrile.

When the electrolyte comprises a solvent, the first and second redox products are preferably not derived from electrolysis of the solvent.

The second redox product is any oxidation or reduction product that is capable of modifying a substrate. The second redox product may be generated directly by oxidation or reduction of a substance in the electrolyte. Alternatively, the second redox product may be generated indirectly by oxidation or reduction of a substance in the electrolyte followed by one or more subsequent reactions with other substance(s) in the electrolyte.

Generally, the second redox product is generated at the surface of a second electrode. The second redox product may then modify a substrate in the vicinity of the surface of the second electrode, such as a substrate facing the electrode. An acid is a preferred example of a second redox product. An acid may be involved in many types of reaction on a substrate, for example eliminations, substitutions, rearrangements and chemical etching. Preferably, when the second redox product is an acid, the acid is used to remove an acid labile protecting group from a substrate. Suitable acids include Lewis acids and Bronsted acids e.g. metal cations, sources of H⁺ and H⁺ itself.

Acid labile protecting groups are well known to a person skilled in the art and include, for example, acetals (e.g. methoxymethyl, methylthiomethyl, (2-methoxyethoxy)methyl, benzoyloxymethyl, β-(trimethylsilyl)ethoxymethyl, tetrahydropyranyl, benzylidene, isopropylidene, cyclohexylidene, cyclopentylidene), esters (e.g. benzoyl, benzoyloxycarbonyl, tert-butoxycarbonyl), ethers (e.g. trityl, dimethoxytrityl, tert-butyl) and silyl ethers (e.g. tert-butyldimethylsilyl, trimethylsilyl, triethylsilyl). Preferably, the acid labile protecting group is a trityl or dimethoxytrityl (DMT) ether, which are protecting groups commonly used in the synthesis of oligonucleotides.

Preferably, in the method of the present invention, the substrate to be treated comprises a substance having an acid-labile protecting group. In this preferred embodiment, the treatment is performed by connecting at least one second electrode as an anode at a potential which generates an acid in the electrolyte. The acid generated may then remove an acid-labile protecting group from the substance bound to the surface in the region adjacent the anode.

Alternatively, an acid may be involved in any organic or inorganic reaction promoted by acid. The skilled person will be aware of a very large number of potential reactions which could be adapted for use with present invention. Examples of organic reactions include epoxide openings, additions to multiple bonds, rearrangements, substitutions (e.g. S_{N}1 substitution of a tertiary alcohol), eliminations, formation of enols with subsequent reactions of the enol, and simple protonation of organic acid salts.

The second redox product may be a base. Bases may be involved in many types of reaction on a substrate. For example, a base may be used to remove a base-labile protecting group. Suitable bases include Lewis bases.

Base-labile protecting groups are well known to a person skilled in the art and include, for example, 9-fluorenylmethoxycarbonyl (Fmoc) and cyanoethyl groups.

Radicals are another example of the second redox product. Radicals may be used to initiate radical reactions on a substrate. Electrochemical methods for generating radicals will be well known to the skilled person. One commonly used method for electrochemically generating a radical is the oxidation of carboxylate anions. Suitable radicals include neutral, positively charged and negatively charged species.

Halogens are another example of the second redox product. Halogens may be used in, for example oxidation reactions or addition reactions on a substrate. Halogens may be produced electrochemically by oxidation of the corresponding halide ion.

When the second redox product is a halogen, the halogen may be involved in mild oxidations, bleaching a substrate or halogenations. The second redox product may also be a halide ion, which may used in substitution reactions.

The second redox product may be an electrophile. The second redox product may be a nucleophile.

The second redox product may be more positively charged than the group or atom of the substrate with which it reacts. The second redox product may be more negatively charged than the group or atom of the substrate with which it reacts.

The second redox product may be a cation. The second redox product may be an anion. The second redox product may be neutral.

These and other examples of the second redox product will be readily apparent to the skilled person.

The method of the present invention is similar to the method described in WO93/22480. However, the method of the present invention differs in the arrangement of the first and second electrodes. Furthermore, the method of the present invention differs in the choice of electrolyte. WO93/22480 employs an electrolyte which is triethylamine and sulphuric acid in acetonitrile. The present invention uses an electrolyte in which the second redox product is quenchable by a first redox product. An advantage of this electrolyte is that it is possible to confine the second redox product to the region immediately surrounding the electrode by which it was generated, thereby leading to high resolution of the patterning of the substrate.

In the method described in WO93/22480, the confinement of an acid at a specific region is controlled by variation of the electrode potential. Applicants have found that after prolonged electrolysis, the acid is unconfined when the electrolyte is triethylamine and sulphuric acid in acetonitrile. Poor confinement of acid leads to poor resolution of the substrate being treated. For example, protons which diffuse away from the immediate vicinity of the anode may react at the substrate in the zone between electrodes. The adventitious reaction of diffused protons in this way is undesirable from the point of view of obtaining high resolution patterned substrates.

In the method described in WO03/20415, an initial redox product produced by an electrode is confined in a specific region by using a particular type of electrolyte such that switching the surrounding electrodes produces a further redox product which is able to quench the initial redox product. However, the requirement to have to individually address each of the surrounding electrodes means that highly complicated electronics are required where a large number of electrodes are used in the method. The resolution of the electrochemical patterning method in WO03/20415 is limited by the number of electrodes which can be individually addressed per unit area of an array.

By choosing an electrolyte and an arrangement of the common first electrode and second electrodes in accordance with the present invention, the problems of the prior art methods may be avoided.

The skilled person will be aware of many examples of electrolytes which produce a second redox product that is quenchable by a first redox product.

An example of such an electrolyte is a combination of I⁻ and S₄O₆²⁻. Oxidation of iodide at the anode produces iodine (which is the second redox product when the second electrodes are anodes), while reduction of S₄O₆²⁻ at the cathode produces S₂O₃²⁻; which may quench the iodine generated at the anode. The reactions in the electrolyte may be represented as follows:

Anode: 2I⁻−2e⁻→I₂

Cathode: S₄O₆²⁻+2e⁻→2S₂O₃²⁻

Iodine is quenched by the reaction: 2S₂O₃²⁻+I₂→S₄O₆²⁻+2I⁻

Preferably, the common first electrode is a cathode and the individually addressable second electrodes are anodes. Preferably, the second redox product is an acid and the first redox product (the quenching species) is an anion, preferably an organic radical anion. Usually, the acid is generated at the anode by oxidation of an alcohol, which may be any aliphatic or aromatic alcohol. In such electrolytes, the quenching anion is usually generated at the cathode by reduction of a suitable substance. Many substances may be reduced at the cathode to produce an anion, which may quench the acid formed at the anode. For example, dissolved molecular oxygen may be reduced at the cathode, thereby generating O₂⁻ and/or O₂²⁻.

An example of an electrolyte that produces suitable first and second redox products is a combination of a ketone and a corresponding alcohol. Oxidation of the alcohol at the anode produces a proton (the active redox product), while reduction of the ketone at the cathode produces a radical anion which may quench the proton generated at the anode. The reactions in the electrolyte may be represented as follows:

Anode: R¹CH(OH)R²→R¹C(O)R²+2H⁺+2e⁻

Cathode: R¹C(O)R²+e⁻→[R¹C(O)R²]⁻

wherein:
R¹ and R² are independently selected from optionally substituted C₁ to C₁₅ hydrocarbyl wherein up to three C atoms may optionally be replaced by N, O and/or S atoms; or R¹ and R² together form an optionally substituted C₁ to C₁₅ cyclohydrocarbylene wherein up to three C atoms may optionally be replaced by N, O and/or S atoms.

Preferably, R¹ and R² are independently selected from optionally substituted C₁₋₈ alkyl, C₃₋₈ cycloalkyl or phenyl groups.

The term “hydrocarbyl” is used herein to refer to monovalent groups consisting of carbon and hydrogen. Hydrocarbyl groups thus include alkyl, alkenyl and alkynyl groups (in both straight and branched chain forms), cycloalkyl (including polycycloalkyl), cycloalkenyl and aryl groups, and combinations of the foregoing, such as alkylcycloalkyl, alkylpolycycloalkyl, alkylaryl, alkenylaryl, alkynylaryl, cycloalkylaryl and cycloalkenylaryl groups.

The term “hydrocarbylene” is used herein to refer to divalent groups consisting of carbon and hydrogen. Cyclohydrocarbylene groups thus include cycloalkylene, cycloalkenylene and arylene groups.

The term “aryl” is used herein to refer to an aromatic group, such as phenyl, naphthyl or anthracyl. Alternatively, when an aryl group has carbon atoms replaced by O, N and/or S, the term aryl refers to a heteroaromatic group, such as pyridyl, pyrrolyl, thienyl, furanyl imidazolyl, triazolyl, quinolinyl, isoquinolinyl, oxazolyl or isoxazolyl.

Where reference is made herein to optionally substituted groups, the substituents are preferably selected from C₁ to C₆ alkyl, C₁ to C₆ alkoxy, thio, C₁ to C₆ alkylthio, carboxy, carboxy(C₁ to C₆)alkyl, formyl, C₁ to C₆ alkylcarbonyl, C₁ to C₆ alkylcarbonylalkoxy, nitro, trihalomethyl, hydroxy, C₁ to C₆ alkylhydroxy, hydroxy(C₁ to C₆)alkyl, amino, C₁ to C₆ alkylamino, di(C₁ to C₆ alkyl)amino, aminocarboxy, C₁ to C₆ alkylaminocarboxy, di(C₁ to C₆ alkyl)aminocarboxy, aminocarboxy(C₁ to C₆)alkyl, C₁ to C₆ alkylaminocarboxy(C₁ to C₆)alkyl, di(C₁ to C₆ alkyl)aminocarboxy(C₁ to C₆)alkyl, C₁ to C₆ alkylcarbonylamino, C₅ to C₈ cycloalkyl, C₅ to C₈ cycloalkyl(C₁ to C₆)alkyl, C₁ to C₆ alkylcarbonyl(C₁ to C₆ alkyl) amino, halo, C₁ to C₆ alkylhalo, sulphamoyl, tetrazolyl and cyano.

As used herein, “halo” or “halogen” refers to iodine, bromine, chlorine or fluorine.

The nature of R¹ and R² may be varied to change the redox characteristics of the electrolyte. For example, the introduction of substituents on R¹ and R² may change the potential at which oxidation or reduction occurs.

Preferred examples of ketone/alcohol electrolytes are 2-propanone/iso-propanol and benzophenone/benzhydrol, in a suitable organic solvent.

Another example of a suitable electrolyte is benzoquinone/hydroquinone and derivatives thereof. Such electrolytes may be a combination of:

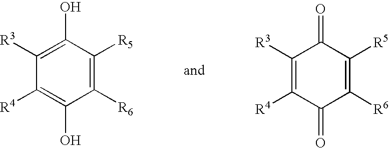

wherein (a) R³, R⁴, R⁵ and R⁶ are independently selected from: hydrogen, halo, nitro, hydroxyl, thio, nitro, amino, and optionally substituted C₁ to C₁₅ hydrocarbyl wherein up to three C atoms may optionally be replaced by N, O and/or S atoms; or (b) R³ and R⁴ and/or R⁵ and R⁶ together form an optionally substituted C₁ to C₁₅ cyclohydrocarbylene wherein up to three C atoms may optionally be replaced by N, O and/or S atoms.

Preferably, R³, R⁴, R⁵ and R⁶ are independently selected from hydrogen, optionally substituted C₁₋₈ alkyl or R³/R⁴ and R⁵/R⁶ together form an optionally substituted C₅-C₁₂ arylene group, such as phenylene.

The nature of R³, R⁴, R⁵ and R⁶ may be varied to change the redox characteristics of the electrolyte, for example to alter the precise potential at which oxidation or reduction occurs. Preferred examples of electrolytes based on benzoquinone/hydroquinone derivatives are anthraquinone/anthraquinol and duroquinone/duroquinol, in a suitable organic solvent.

In a preferred embodiment, the electrolyte comprises a mixture of benzoquinone and hydroquinone in acetonitrile. Where the common first electrode is a cathode and the second electrodes are anodes, this mixture provides a second redox product which is a hydrogen ion. The hydrogen ions (protons) are quenchable by a benzoquinone radical anion (the first redox product).

Specifically, hydroquinone is oxidised at the anode to produce benzoquinone and protons:

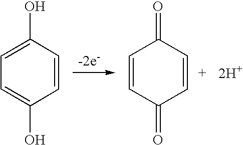

The protons liberated by the oxidation of hydroquinone are mostly localised at the anode and may modify a substrate adjacent thereto. For example, the protons may deprotect a substrate bearing an acid labile protecting group.

Benzoquinone is reduced at the cathode to produce a benzoquinone radical anion:

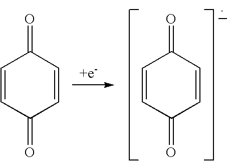

The benzoquinone radical anion is a relatively stable species in solvents such as acetonitrile. This radical anion quenches any adventitious protons which escape from the immediate vicinity of the anode, in accordance with the following reaction:

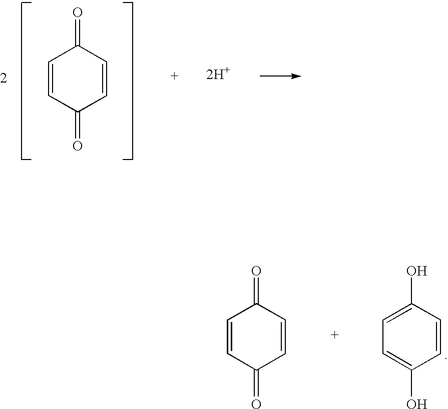

### In this way, the resolution of a region of a substrate being treated may be improved by localising the second redox product, for example, a proton generated at the anode.

### Salt Concentration

Electrochemical systems have a background electrolyte, which is the redox products generated by the electrochemical reaction. In most electrochemical systems in the prior art, the electrolyte additionally comprises a conductivity enhancer, i.e. a substance which increases the conductivity of the electrolyte, such as an inert conductive salt. Generally, it is desirable to increase the conductivity of the electrolyte so that electrolysis may be performed at lower voltages than in the absence of a conductivity enhancer. Addition of an inert but conductive salt eliminates electric field induced migration, which means that the redox products are able to undergo free diffusion through the electrolyte. Any ionic substance which is soluble in the electrolyte is suitable for this purpose. For example, when the electrolyte comprises an organic solvent such as acetonitrile, a suitable conductivity enhancer may be a tetra(C₁₋₈ alkyl) ammonium salt, such as tetrabutylammonium hexafluorophosphate.

However, in the present invention where there is a common first electrode, the presence of a conductive salt causes the current density at the common first electrode to be spread across its entire surface. This means that when the potential of a specific second electrode is altered and a second redox species is generated, the first redox product (which will be generated in a stoichiometric amount) is distributed across the entire surface of the common first electrode, and so is present at only a low concentration in the vicinity of the specific second electrode. Thus, there will be less first redox product available in the vicinity of the specific second electrode for quenching which means that the second redox product will not be confined to substantially the cell in which the specific second electrode is located. Therefore, the presence of the inert conductive salt leads to a reduction in resolution of the substrate patterning. An obvious way of overcoming this problem is to have separate individually addressable first electrodes (e.g. WO03/20415). However, to take advantage of arrays of electrodes already available for high resolution LCDs, which use a common cathode, the inventors have now surprisingly found that it is necessary to lower the amount of inert conductive salt. Where the distance between a second electrode and the part of the common first electrode defining its cell is very small, as in LCD screens, eliminating the inert conductive salt or decreasing the amount of inert conductive salt to very low levels, results in high current density at the portion of the common first electrode closest to the second electrode. Thus, a high concentration of the first redox product is generated at the portion of the common first electrode nearest the second electrode, permitting efficient confinement of the second redox product to the region of the substrate to be modified. This enhanced resolution comes at the cost of lower electrolyte conductivity. However, where the distance between the common first electrode and the second electrodes are small, this has little effect on the overall current-carrying capacity of the device.

The amount of inert conductive salt which can be tolerated in the electrolyte depends on the particular spacing between the second electrodes and their closest portion of the common first electrode and of the particular resolution required in the electrochemical patterning process. So, as the patterning resolution required is increased, the level of inert conductive salt tolerated is reduced. The range of concentrations of inert conductive salt appropriate for use in any particular case may be deduced by routine experimentation since at any given salt concentration it is possible to work out the diffusion of the redox species when using a common electrode.

Changes in the inert conductive salt concentration may alter the chemistry of the overall redox reactions, thereby enhancing or decreasing the amount of first and second redox products generated. Changes in the relative amounts of first and second redox products will affect the extent of substrate modification and quenching that occurs. However, the affect of changing the inert salt concentration may be easily determined by routine experimentation. As such, a range of concentrations of inert conductive salt appropriate for use in any particular case may be deduced readily.

Depending on the resolution required in the patterning process, the amount of inert conductive salt in the electrolyte is typically less than 25 mmolar, 20 mmolar, 15 mmolar, 10 mmolar, 5 mmolar, 1 mmolar, 0.5 mmolar, 0.1 mmolar, 0.05 molar, or 0.01 mmolar, etc. Preferably the electrolyte comprises substantially no inert conductive salt.

### Substrate

The substrate used in the method of the present invention may be any material or substance that is able to be modified by the second redox product.

In one embodiment, the substrate is the surface of a material which is separate from and facing the electrodes. Typically, in this embodiment, the substrate is removed from the vicinity of the electrodes after the redox reaction has taken place.

The substrate material may be impermeable or permeable. Suitable substrates include glass, plastic (e.g. polyacrylamide or nylon), solid fibre matrix (e.g. filters or membranes), metal (e.g. gold), semiconductor, silicon oxide or gel materials (e.g. polyacrylamide gel). Preferably the substrate is a glass slide.

The substrate may be attached to an underlying support material.

The surface of the material may be derivatised to assist with attachment of organic species. Typically, silanes of the general formula (RO)₃SiR′ are used to modify the material surface, particularly glass surfaces, prior to linker and/or attachment of organic species. Silanes are particularly preferred in applications where oligonucleotides are to be attached to the surface. Suitable silanes include glycidoxypropyltriethoxysilane, (3-aminopropyl)triethoxysilane, N-(3-diethoxymethylsilylpropyl)bromoacetamide, N-(3-dimethylethoxysilylpropyl)bromoacetamide, N-(4-diisopropylmethoxysilylbutyl)bromacetamide, (3-glycidyloxypropyl)trimethoxysilane, aminophenyltrimethoxysilane, (3-mercaptopropyl)trimethoxysilane, and (3-aminopropyl)trimethoxysilane. Preferably, glycidoxypropyltriethoxysilane is used where the material is glass.

Organic species may be attached to the surface of the material or derivatised material covalently or non-covalently. Preferably, the organic species are attached to the surface of the material by a linker or spacer. Linkers and spacers molecules are typically added after surface derivatisation steps which act to remove the steric interaction between the oligonucleotide and the solid support. Suitable linkers or spacers include polyethylene glycol, 4-nitrophenyl-chloroformate, acryloylchloride, diisopropylethylamine, tetraethylenpentamine, 1,4-bis-(3-aminopropoxy)butane, 4-aminomethyl-1,8-octadiamine, 4,7,10-trioxa-1,13-tridecandiamine, N,N-dimethyl-1,6-hexadiamine, 3-amino-1,2-propandiol, 1-ethyl-3-(3-dimethylaminopropyl)-carbodiimide hydrochloride, phenyldiisothiocyanate, 2-(2-aminoethoxy)ethanol, maleic anhydride, m-maleimidobenzoyl-N-hydroxysulfo-succinimide ester, sulfosuccinimidyl (4-iodoacetatyl)aminobenzoate, sulfosuccinimidyl 4-(N-maleimidomethyl)-cyclohexane-1 carboxylate, N-(γ-maleimidobutyryloxy)sulfo succinimide ester, and sulfosuccinimidyl 4-(p-maleimidophenyl)-butyrate.

Preferably, where a glass substrate material is used in DNA growth applications, glycidoxypropyltriethoxysilane is used to derivatize glass followed by acid-catalysed attachment of polyethylene glycol to which DNA phosphoramidite may then be covalently attached.

The surface of the material itself may be modified by the redox reaction. Alternatively, organic species attached to the surface of the material may be modified by the redox reaction.

In an alternative arrangement, the method is as described above but the first and/or second electrodes are themselves modified by the electrochemically-generated redox products. Typically, organic species that can be modified by the second redox product are attached to the second electrodes. Advantageously, electrodes can be used to detect and/or modulate hybridisation (e.g. as reviewed by Thorp (1998) TiBtech 16:117-121). Conductive linkers may be used (e.g. see U.S. Pat. No. 6,221,583). Attachment of biopolymers to the surface of a sensor (e.g. the gate of a field effect transistor) such that a binding interaction changes the sensor's physical characteristics is disclosed in U.S. Pat. No. 4,562,157, and photoinduced electron transfer through DNA helices is disclosed by Murphy et al. (1993) Science 262:1025-1029.

### Methods

The device of this invention is able to generate redox products in desired patterns, which may then be used to react with specific regions of a substrate, so that the device and the method of this invention may be used in a wide variety of applications.

The device and the method of this invention are useful whenever it is desired to add or remove material from specific regions of a substrate.

At a general level, the redox reaction may be used to deprotect a substrate in specific patterns, i.e. to remove protecting groups from specific regions of a substrate. This leaves a pattern of deprotected groups. Subsequent exposure of the deprotected groups to a reactant allows the deprotected groups to react with the reactant while the protected groups cannot, and in this way complex patterns and reactants can be laid down.

The deprotected groups may be exposed to a reactant either in the electrolyte or in a separate reactant solution. Where a reactant solution is used, there may be cycling of the electrolyte and the reactant solution (e.g. by having the device of the invention as part of a flow cell).

Patterning may be by repeated deprotection, which is particularly good for allowing stepwise synthesis, such as combinatorial synthesis. The subsequent deprotecting steps may be to the same and/or different areas of the substrate. By performing several treatments in sequence, polynucleotides or other polymers, or products formed by combinatorial chemistry on the substrate may be produced.

Preferably, the method of the present invention is used in the stepwise chemical synthesis of polymers, such as polynucleotides, polysaccharides and polypeptides. More preferably, the method of the present invention is used in the synthesis of polynucleotides, and offers an alternative to the light-directed combinatorial techniques described by Fodor et al. (1991) Science 251:767-763 (see also U.S. Pat. No. 5,143,854), by Lipshutz et al. (1999) Nature Genet 21:20-24, and by Singh-Gasson et al. (1999) Nature Biotechnol 17:974-978 (see also U.S. Pat. No. 6,375,903). Polynucleotides between 8 and 100 nucleotides in length are preferred. The method of the present invention may be used in the synthesis of libraries of small organic compounds bound to a surface (see, for example, Schreiber, (2000) Science 287:1964-1969). Libraries of small organic compounds are important in the field of drug discovery. The range of reactions to which the present method may be applied means it is ideally suited to the synthesis of such libraries.

Alternatively, patterning may involve a single deprotection step per cell. For example, deprotection may expose reactive groups on the substrate which are then able to react with something, such as a pre-synthesised polypeptide or polynucleotide.

Following deprotection, however, the deprotected groups need not be exposed to a reactant. This may be desirable where, for example, etching of the substrate is required, such as during the production of semiconductor circuitry or microfluidic structures.

The method of this invention may also be used during the production of organic LED (OLED) compounds. Typically, in OLEDs organic photoluminescent or electroluminescent materials are attached to an ITO film or to an organic layer over an ITO film. A problem encountered in making OLED screens is that it is necessary to print organic photoluminescent or electroluminescent materials at a high resolution over a very large area. The method of this invention enables the attachment of organic photoluminescent or electroluminescent materials to specific areas of a substrate, such as ITO, at very high resolution and over a very large area.

Examples of suitable organic photoluminescent or electroluminescent materials are fluorescent light emitting polymers (e.g. polyphenylene vinylene (PPV) and its derivatives, including poly[p-phenylene vinylene]), fluorescent small organic molecules (e.g. tris-(8-hydroxyquinoline) aluminium (Alq3)), phosphorescent small organic molecules (e.g. 2,3,7,8,12,13,17,18-octaethyl-21H, 23H-porphine platinum (II) (PtOEP) and europium (triphenylphosphinoxide) ₂(thenoyltrifluoroacetonate))₃ and fluorescent or phosphorescent dendrimers (e.g. comprising a fac-tris(2-phenylpyridine) iridium core, phenylene dendrons, or 2-ethylhexyloxy surface groups).

In OLED manufacture, an intermediate layer is preferably positioned between the ITO layer and the electroluminescent or photoluminescent material and acts e.g. as a charge-injection layer (e.g. to assist in hole injection) and/or as a passivation layer. The intermediate layer may be deposited on the ITO using the method of the present invention. The intermediate layer may be polymeric (e.g. a mixture of poly(3,4-ethylene dioxythiophene) and poly(4-styrene sulphonate) (PEDOT) or poly(N-vinyl carbazole)) or may comprise a layer of small organic molecules (e.g. copper phthalocyanine (CuPc), N,N′-diphenyl-N,N′-bis (3-methylphenyl)-1,1′-biphenyl-4,4′-diamine (TPD), bis (naphthalen-2-yl)-N,N′-bis (phenyl) benzidine (NPD), 4,4′-di(N-carbazole) biphenyl (CBP), 4,4′,4″-tris(N-(3-methylphenyl)-N-phenylamine)triphenylamine (MTDATA), perylene-3,4,9,10-tetracarboxylic-3,4,9,10-dianhydride (PTCDA), N,N′-bis-(1-napthyl)-N,N′-diphenyl-1,1′-biphenyl-4,4′diamine (NPB)).

CFx, where x is 3 or 4, and organosilanes (e.g. 1,1,1,3,3,3-hexamethyldisilazane (HMDS) or alpha-aminopropyltriethoxysilane (APTES) are further examples of passivation layers suitable for use on ITO, which may be attached to ITO using the method of this invention.

Preferably, multiple layers (e.g. at least 2, at least 3, at least 4 or at least 5 layers) of organic material are deposited using the method of the present invention during OLED screen manufacture.

The invention also provides a method for guiding a reagent along the face of a substrate in a desired path, wherein a device of the invention is used to create redox products along the desired path, and wherein the reagent moves (e.g. diffuses or grows) into the region(s) where the redox products are created. This method allows complex flow patterns to be established without fabrication of actual flow channels on a substrate.

Multiple substrates may be used simultaneously with a device of the invention. For example, glass slides can be tiled over a large device of the invention. Typically, the second electrodes of the device may be switched on and off in a sequence that produces the same pattern on each of the multiple substrates. In this way, a number of identically patterned substrates may be produced in a single process, thereby increasing the throughput and efficiency of the product production.

A preferred method for preparing an array of polynucleotides comprises the steps of:
(1) providing a substrate having protecting groups on its surface and which faces the device of the invention and is in contact with the electrolyte;
(2) switching a first set of second electrodes so as to generate a second redox product which exposes deprotected groups by removing a set of protecting groups from the substrate;
(3) coupling a nucleotide to the set of deprotected groups, the nucleotide comprising a protecting group; and
(4) repeating the sequence of steps (2) and (3) until the desired array has been generated.

In the repetitions, the product of step (3) thus becomes the substrate for step (2).

The substrate initially provided in step (1) may already have nucleotides coupled to it.

As well as using single nucleotides in step (3), dinucleotides, trinucleotides, etc. can also be used to build up desired sequences. Thus, step (3) may involve the use of an oligonucleotide having n bases, where n is 1, 2, 3, 4, or 5. Typical nucleotide reagents used in step (3) are phosphoramidites.

When this method is used in the synthesis of polynucleotides, the second redox product is preferably a proton and the protecting group is preferably an acid-labile protecting group, such as a trityl or dimethoxytrityl (DMT) group which protects a furanyl hydroxyl group. The skilled person will appreciate that this method is particularly suited to the combinatorial synthesis of DNA arrays, as described in WO93/22480.

Polynucleotides which may be synthesised according to the invention include DNA, RNA, DNA/RNA hybrids, as well as polynucleotides comprising modified backbones (e.g. phosphorothioates, 2′-O-methylation, peptide nucleic acids, etc.). They may contain natural bases (A, C, G, T/U) or other bases (e.g. deoxyinosine, deoxyuridine, halogenated bases, etc.). Polynucleotides may be single-stranded or double-stranded, but are preferably single-stranded. Polynucleotides may be labelled (e.g. with a fluorescent label, with biotin, etc.).

The invention is particularly useful for forming substantially parallel lines of polynucleotides. These parallel lines of polynucleotides may be arranged on the surface of a substrate also comprising channels (e.g. microfluidic channels) on its surface. The polynucleotide lines may be substantially orthogonal to the channels.

The method of this invention may also be used in the synthesis of polypeptides. For example, peptides may be synthesised by sequential removal of t-butyloxycarbonyl (Boc) protecting groups from nitrogen atoms using protons generated at the anode. Other polymer syntheses will be readily apparent to a person skilled in the art.

Following synthesis, the polynucleotides may be cleaved from the surface of the material. Preferably, the device of the invention may itself be used to cleave the polynucleotides, for example by altering the potential of the second electrodes. This may be particularly useful where it is desired to cleave only certain polynucleotides at any one time, in which case a specific second electrode may be used to cleave specific areas of polynucleotides from the surface of the material.

### General

The term “comprising” means “including” as well as “consisting” e.g. a composition “comprising” X may consist exclusively of X or may include something additional e.g. X+Y.

The term “about” in relation to a numerical value x means, for example, x±10%.

The word “substantially” does not exclude “completely” e.g. a composition which is “substantially free” from Y may be completely free from Y. Where necessary, the word “substantially” may be omitted from the definition of the invention.

### BRIEF DESCRIPTION OF DRAWINGS

FIGS. 1 to 6 are different embodiments of a device of the invention.

FIG. 7 is a cross-sectional view of the device of FIG. 1 facing a substrate attached to the device, whereas in FIG. 8 the substrate is spaced apart from the device.

FIG. 9 is a cross-sectional view of a further embodiment of the device of the invention, and

FIG. 10 is a plan view of the same embodiment.

FIG. 11 is a perspective view of a further embodiment of the device of the invention, facing a substrate.

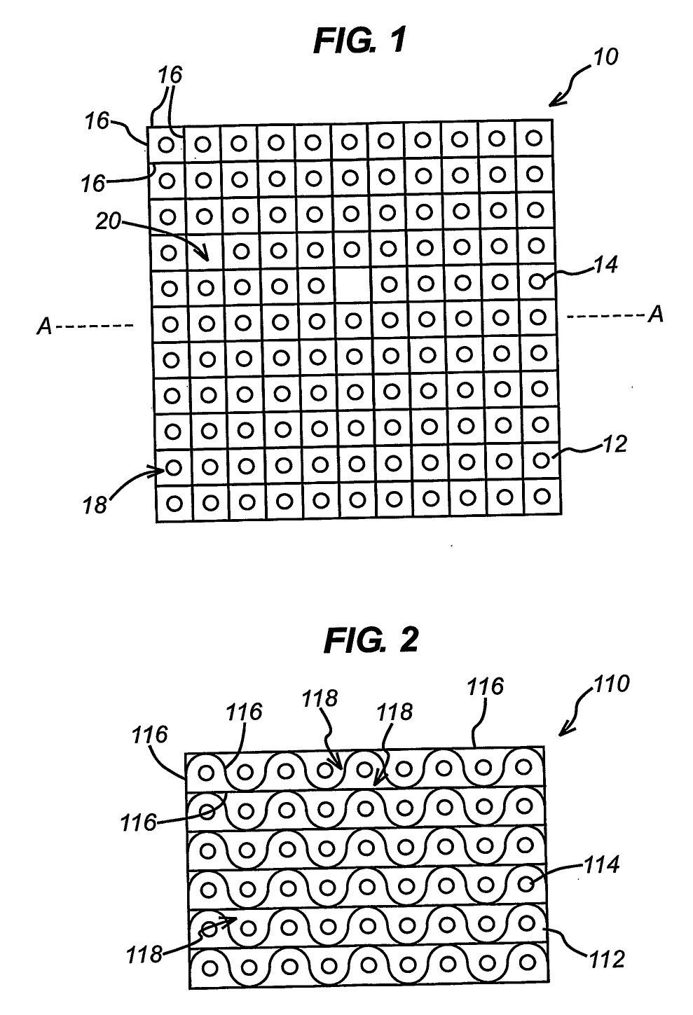

None of FIGS. 1 to 11 shows the electrical connections required to individually address the second electrodes.

### MODES FOR CARRYING OUT THE INVENTION

### Electrode Arrangements

FIGS. 1 to 6 show various embodiments of a device (10) for electrochemically modifying the surface of a substrate (not shown). In FIG. 1, a first embodiment of the device (10) has an array of individually addressable second electrodes (14). The second electrodes (14) are circular and are mounted on a support (12). A common first electrode (16) is arranged on the support (12) in the form of a grid. The common first electrode (16) defines cells (18, 20). Most cells (18) contain a single second electrode. A minority of cells (20) do not contain a second electrode.

In FIG. 2, there is shown a portion of a second embodiment of a device (110). The device (116) has an array of individually addressable second electrodes (114). The second electrodes (114) are mounted on a support (112). A common first electrode (116) is arranged on the support (112) in tessellating pattern. The common first electrode (116) defines cells (118). In the portion of the device (110) shown in FIG. 2, a single second electrode (114) is positioned within each cell (118).

In a third embodiment of the device (210), a portion of which is shown in FIG. 3, there is an array of individually addressable second electrodes (214). The second electrodes (214) have a square shape and are mounted on a support (212). A common first electrode (216) is arranged on the support in a net-like pattern. The common first electrode (216) defines cells (218). In the portion of the device (210) shown in FIG. 3, a single second electrode (214) is positioned within each cell (218).

In a fourth embodiment of the device (310), a portion of which is shown in FIG. 4, there is an array of individually addressable second electrodes (314). The second electrodes (314) are mounted on a support (312). A common first electrode (316) is arranged on the support in an irregular pattern. The common first electrode (316) defines cells (318). In the portion of the device (310) shown in FIG. 4, a single second electrode (314) is positioned within each cell (318). The common first electrode (316) is arranged such that many of the cells are not completely surrounded by a portion of the common first electrode (316). Small gaps (320) can exist in the common first electrode (316) defining the cells (318).

In a fifth embodiment of the device (410), a portion of which is shown in FIG. 5, there is an array of individually addressable second electrodes (414) mounted on a support (412). A common first electrode (416) is arranged on the support in a honeycomb pattern. The common first electrode (416) defines cells (418). In the portion of the device (410) shown in FIG. 5, a single second electrode (414) is positioned within each cell (418).

In a sixth embodiment of the device (510), a portion of which is shown in FIG. 6, there is an array of individually addressable second electrodes (514) mounted on a support (512). A common first electrode (516) is arranged on the support in a rectilinear grid pattern and defines cells (518). In the portion of the device (510) shown in FIG. 6, two second electrodes (514) are positioned within each cell (518).

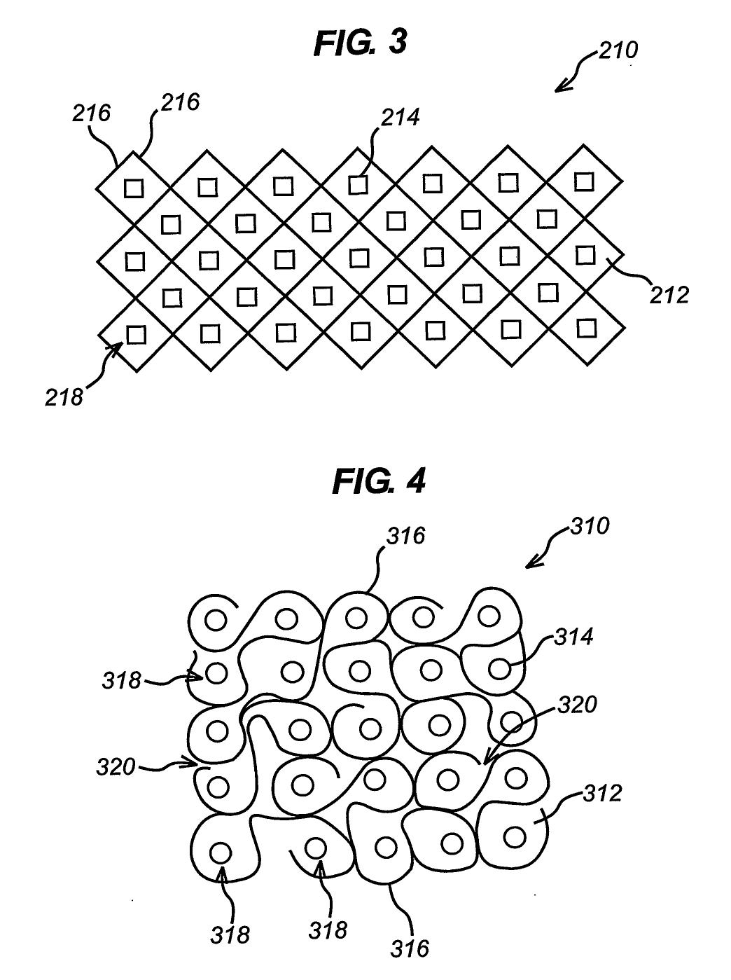

Part of the cross-section along line A-A in FIG. 1 is shown in FIG. 7. In FIG. 7, the first embodiment of the device in FIG. 1 is shown in contact with electrolyte (22) and the device is arranged to face a glass substrate (40). The glass substrate (40) is spaced from the device (10) but is also in contact with the electrolyte (22). The edges (32) of the cells (18) as they pass through the electrolyte are indicated by dashed lines. A polymer species (26) having a protecting group (28) is attached to the substrate (40) by a linker group (30). The electrolyte (22) is such that when the potential of a particular second electrode (14) is altered, the second electrode (14) is able to generate a second redox product (34) which can remove the protecting group (28) from the substrate (40) facing the particular second electrode (14). The common first electrode (16) generates a first redox product (36) which is able to quench the second redox product (34). In this way, the second redox product (34) generated by the second electrode (14), is substantially confined to the cell (18) in which that second electrode is positioned, thereby increasing resolution of the patterned substrate by preventing the second redox product from removing the protecting group (28) in the region of the substrate (40) facing neighbouring cells.

In FIG. 8, the first embodiment of the device in FIG. 1 is again shown in contact with electrolyte (822). However, in FIG. 8 the device is being used in an alternative arrangement in which the second electrodes (814) are themselves modified by the electrochemically-generated redox products. The edges (832) of the cells (818) as they pass through the electrolyte are indicated by dashed lines. Polymer species (826) having protecting groups (828) are attached to the individually addressable second electrodes (814) by a linker group (830). The electrolyte (822) is such that when the potential of a particular second electrode (814) is altered, the second electrode (814) is able to generate a second redox product (834) which can remove the protecting group (828) from the polymer species (826) attached by the linker group (830) to the particular second electrode (814). The common first electrode (816) generates a first redox product (836) which is able to quench the second redox product (834). In this way, the second redox product (834) generated by the second electrode (814), is substantially confined to the cell (818) in which that second electrode is positioned, thereby increasing resolution of the patterned second electrodes (814) by preventing the second redox product from removing the protecting groups (828) of polymer species attached to neighbouring second electrodes (814).

When the device (510) shown in FIG. 6 is used to electrochemically modify a substrate, the resolution in direction (a) is twice as high as the resolution in direction (b) since the arrangement of the common first electrode (516) is such that there is no confinement of the second redox product between the pairs of second electrodes (514) in the cells (518).

Once the protecting groups (28) have been removed from the desired regions of the substrate (24), the electrolyte (22) is washed out from contact with the device (10) and a solution containing protected monomer is introduced. Monomer is able to couple with the parts of the substrate where the protecting groups (28) have been removed, thereby enabling growth of the polymer in specific regions of the substrate.

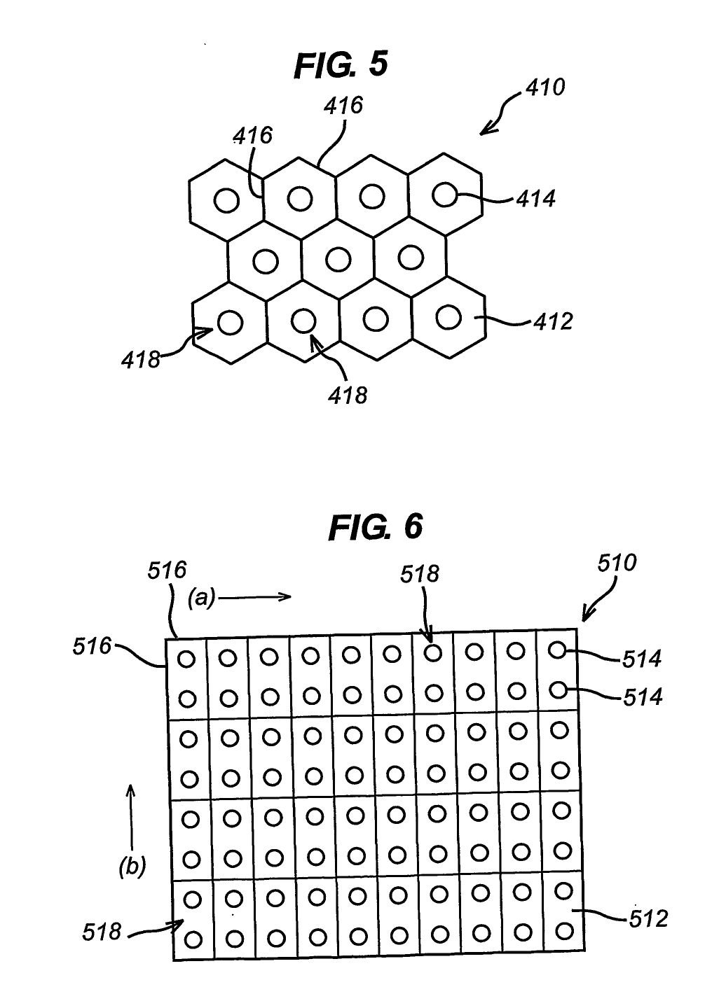

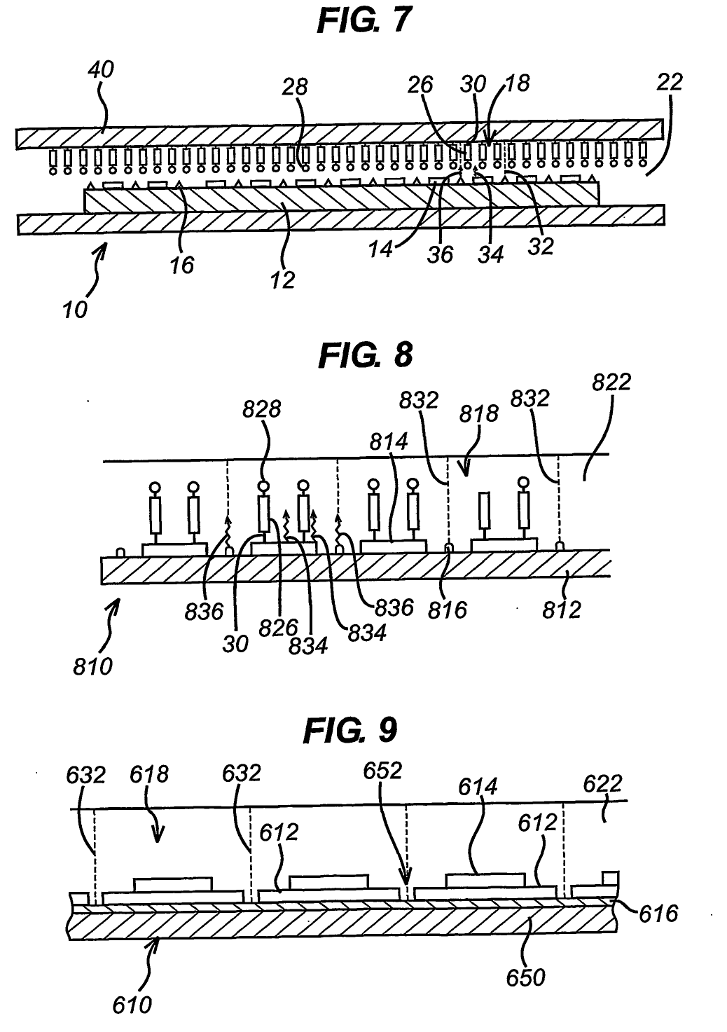

Referring to FIGS. 9 and 10, a further embodiment of the device (610) has an array of individually addressable second electrodes (614). Each second electrode (614) is mounted on a support (612) of insulating material. The supports (612) are mounted on a common first electrode (616) in the form of a metal sheet. The common first electrode (616) is mounted on a second support (650) of insulating material. The supports (612) for the second electrodes are arranged on the common first electrode (616) such that there exists a gap (652) between neighbouring second electrode supports (612). The gap (652) reveals parts of the common-first electrode (616) which are in contact with the electrolyte (622). The parts of the common first electrode (616) revealed by the gap (652) defines cells (618). The edges (632) of the cells (618) as they pass through the electrolyte are indicated by dashed lines.

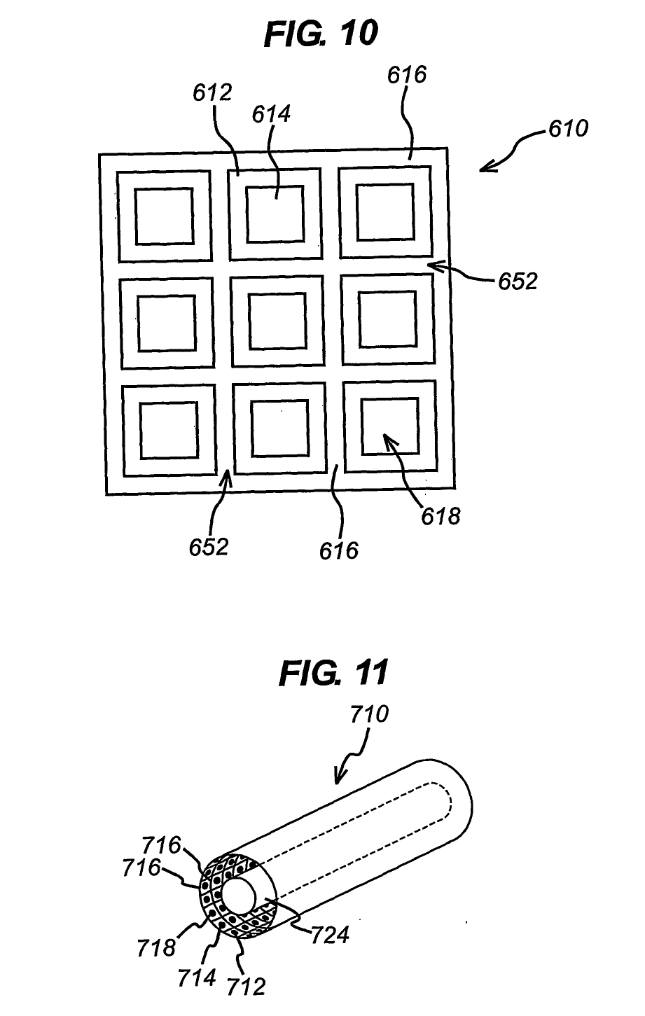

In the embodiment shown in FIG. 11, a device as shown in FIG. 1 is formed into a cylindrical device (710) in which the individually addressable second electrodes (714) and the common first electrode (716) are mounted on a support (712) facing inwardly towards the centre of the cylinder. A cylindrical substrate (724) is able to fit within the cylindrical device (710) such that the second electrodes (714) are able to face the substrate (724). Electrolyte (not shown) fills the gap between the concentric cylinders (710 and 724).

### Device Based on LCD Screen

A device of the invention is made by obtaining from an LCD display production plant an array of anodes mounted on a glass support. The anode array has circuitry such that each anode can be individually addressed. The array of anodes is intended for a RGB colour laptop computer screen and has 4800×1200 anodes arranged in a rectangular array. The dimension of the anodes in the direction in which there are 4800 anodes is a third of that in the direction in which there are 1200 anodes.

A rectilinear grid of iridium is deposited onto the glass support, between each of the anodes in the array. The iridium grid forms a common cathode.

The glass support is then integrated into a flow cell, in which benzoquinone/hydroquinone electrolyte is introduced. The arrangement of the device is such that the anodes and the common cathode are in contact with the electrolyte.

A glass slide substrate derivatized with trityl linker molecules is positioned in the flow cell such that it contacts the benzoquinone/hydroquinone electrolyte and such that it faces the array of anodes and the common cathode.

The potential of each of the anodes forming a diagonal cross in the array is altered such that the anodes produces hydrogen ions and the common cathode produces benzoquinone radical anions.

The electrolyte is washed through the flow cell and is replaced with a solution of equal volumes of acetic anhydride and dimethylaminopyridine, which renders the regions of the substrate subject to the hydrogen ions unreactive towards further chemical modification. Remaining trityl groups are removed by washing dichloroacetic acid through the flow cell. Cy5 phosphoramidite is washed through the flow cell. The substrate is removed from the flow cell and allowed to dry in air.

Examination of the substrate using a Leica TCS NT confocal microscope shows fluorescence everywhere except in a well-defined cross-like image. This indicates that Cy5 phosphoramidite couples only to the regions of the substrate directly facing the anodes that do not generate hydrogen ions, i.e. those areas of the substrate that are not detritylated by the hydrogen ions.

### Salt Concentration

Devices were prepared having a series of second electrodes separated from the first electrode by 80 μm, 160 μm, 240 μm and 320 μm. The electrodes were immersed in an electrolyte solution comprising 25 mM hydroquinone and 25 mM benzoquinone. In a first experiment, 25 mM tetrabutylammonium hexafluorophosphate (TBAHFP), which is an inert conductive salt, was added to the electrolyte solution. In a second experiment, no TBAHFP was added to the electrolyte solution.

Electrodes were positioned facing a glass substrate, which had been derivatized with glycidoxypropyltrimethoxysilane and on which poly(ethylene glycol) linker, followed by DMT-containing phosphoramidite, had been attached in the manner described in Anal. Chem., 2002, vol. 74, 1590-1596. A potential difference of 1.33 V was applied to each second electrode with respect to the first electrode for 15 seconds. The extent of the interaction of the second redox product with the substrate was examined by using the fluorescence detection method described in Anal. Chem., 2002, vol. 74, 1590-1596.

Confocal microscopy revealed that, for the electrolyte containing 25 mM TBAHFP, modification of the substrate occurred within the full region defined by the furthest second electrode. However, for the electrolyte without added TBAHFP, modification of the substrate was limited to the region defined by the nearest second electrode. This demonstrates the suitability of the device of the present invention in high resistance electrolyte solutions for modifying a substrate at high resolution, even with a large common electrode.

It will be understood that the invention has been described by way of example only and modifications may be made whilst remaining within the scope and spirit of the invention.

1. A method of electrochemically treating a substrate, which method comprises the steps of:
(a) providing an electrolyte in contact with the substrate;
(b) providing a device which faces the substrate and is in contact with the electrolyte, the device having:
(i) a common first electrode arranged to define cells therein; and
(ii) a plurality of individually addressable second electrodes, wherein a plurality of the cells contain individually addressable second electrodes; and
(c) altering the potential of at least one of the second electrodes relative to the common first electrode so that:
(i) the common first electrode generates a first redox product; and
(ii) the at least one of the second electrodes generate a second redox product which is able to modify a region of the substrate facing the at least one electrodes,
wherein the electrolyte is such that the second redox product is quenchable by the first redox product.

2. The method of claim 1, wherein the quenching reaction between the first and second redox products regenerates one or more of the original substances in the electrolyte.

3. The method of any preceding claim, wherein the second redox product is an acid, a base, a radical, or a halogen.

4. The method of any preceding claim, wherein the substrate to be treated comprises a substance having an acid-labile protecting group or a base-labile protecting group.

5. The method of any preceding claim, wherein the first redox product is an anion.

6. The method of claim 5, wherein the anion is an organic radical anion.

7. The method of any preceding claim, wherein the electrolyte comprises: (a) I⁻ and S₄O₆²⁻; (b) a ketone and a corresponding alcohol; (c) 2-propanone and iso-propanol; (d) benzophenone and benzhydrol; or (e) benzoquinone and hydroquinone.

8. The method of claim 7, wherein the electrolyte comprises a mixture of benzoquinone and hydroquinone in acetonitrile, and wherein the second redox product is a hydrogen ion.

9. The method of any preceding claim, wherein the electrolyte contains less than 25 mmolar of inert conductive salt.

10. The method of any preceding claim, wherein the substrate is the surface of a material which is separate from and facing the electrodes.

11. The method of any preceding claim, wherein the substrate material is impermeable.

12. The method of any preceding claim, wherein the substrate material is a glass, a plastic, a metal, a semiconductor, a silicon oxide or a gel.

13. A device for electrochemically modifying a substrate, the device having:
(i) a common first electrode arranged to define cells therein; and
(ii) a plurality of individually addressable second electrodes, wherein:
a plurality of the cells contain individually addressable second electrodes;
the common first electrode and the plurality of second electrodes are in contact with an electrolyte during use; and
the electrolyte is such that the common first electrode is able to generate a first redox product, the second electrode is able to generate a second redox product, and the second redox product is quenchable by the first redox product.

14. The device of claim 13, wherein the common first electrode is a cathode and the second electrodes are anodes.

15. The device of any one of claims 13-14, wherein the common first electrode is singly addressable such that the potential of the first electrode may be altered by addressing a single connection.

16. The device of any one of claims 13-14, wherein the common first electrode is a bus line which is neither switchable nor addressable.

17. The device of any one of claims 13-16, wherein the common first electrode has a geometry in which there is a substantially regular pattern, such as a grid, a net, a honeycomb, a series of intersecting circles or other tessellating shapes.

18. The device of any one of claims 13-17, wherein the arrangement of the common first electrode results in at least n×10⁶ cells, where n is 0.5 or more.

19. The device of any one of claims 13-18, wherein the arrangement of the common first electrode is such that the distance between the centre of a cell and the centre of at least one of its immediate neighbour cells is less than 0.5 mm.

20. The device of any one of claims 13-19, wherein the second electrodes are addressed using a direct connection from an electrode to a bond pad on the perimeter of the device, by CMOS switching circuitry, or by transistor-based circuitry.

21. The device of claim 20, wherein the second electrodes are addressed using TFT circuitry.

22. The device of any one of claims 13-21, wherein the distance between the centre of a second electrode and the centre of at least one of its neighbouring second electrodes is less than 0.5 mm.

23. The device of claim any one of claims 13-22, comprising at least n×10⁶ second electrodes, where n is 0.5 or more.

24. The device of any one of claims 13-23, wherein the ratio of the number of cells to the number of second electrodes is less than 1.

25. The device of any one of claims 13-23, wherein the ratio of the number of cells to the number of second electrodes is more than 1.

26. The device of any one of claims 13-23, wherein the ratio of the number of cells to the number of second electrodes is substantially 1.

27. The device of claim any one of claims 13-26, wherein the common first electrode and second electrodes are made from materials independently selected from indium tin oxide, iridium, platinum, palladium, gold, silver, copper, nickel, zinc, titanium, tungsten, aluminium and alloys of these metals.

28. The device of claim 27, wherein the common first electrode and second electrodes comprise a coating of iridium on another material.

29. The device of any one of claims 13-28, wherein the support on which the second electrodes are positioned and the circuitry connecting the second electrodes are as found in liquid crystal display devices.

30. The device of any one of claims 13-29, wherein incorporated into a flow cell arrangement.

31. The method of any one of claims 1 to 12, or the device of any one of claims 13 to 30, for use in deprotecting a substrate in specific patterns.

32. The method or device of claim 31, for use in removing protecting groups from specific regions of a substrate to leave a pattern of deprotected groups, such that subsequent exposure of the deprotected groups to a reactant allows the deprotected groups to react with the reactant.

33. The method or device of claim 31, for use in combinatorial synthesis.

34. The method or device of claim 31, for use in the synthesis of libraries of small organic compounds bound to a surface.

35. The method or device of claim 31, for use in synthesising polymers.

36. The method or device of claim 34, for use in synthesising polynucleotides, polysaccharides, or polypeptides.

37. The method or device of claim 31, for etching of the substrate.

38. The method or device of claim 31, for use in the production of organic LED materials.

39. A method for preparing an array of polynucleotides comprises the steps of:
(1) providing a substrate having protecting groups on its surface and which faces the device of any one of claims 13 to 30 and is in contact with the electrolyte;
(2) switching a first set of second electrodes so as to generate a second redox product which exposes deprotected groups by removing a set of protecting groups from the substrate;
(3) coupling a nucleotide to the set of deprotected groups, the nucleotide comprising a protecting group; and
(4) repeating the sequence of steps (2) and (3) until the desired array has been generated.

40. The method of claim 39, wherein the second redox product is a proton and the protecting group is an acid-labile protecting group which protects a furanyl hydroxyl group.

41. A method for guiding a reagent along the face of a substrate in a desired path, wherein a device of any one of claims 13 to 30 is used to create redox products along the desired path, and wherein the reagent moves into region(s) where the redox products are created.
